(19) United States
(12) Patent Application Publication
(10) Pub. No.: US 2023/0100713 A1
(43) Pub. Date: Mar. 30, 2023

(54) INTEGRATED CIRCUIT STRUCTURES WITH IMPROVED TWO-DIMENSIONAL CHANNEL ARCHITECTURE

(71) Applicant: Intel Corporation, Santa Clara, CA (US)

(72) Inventors: Chelsey DOROW, Portland, OR (US); Kevin P. O'BRIEN, Portland, OR (US); Carl H. NAYLOR, Portland, OR (US); Kirby MAXEY, Hillsboro, OR (US); Sudarat LEE, Hillsboro, OR (US); Ashish Verma PENUMATCHA, Beaverton, OR (US); Uygar E. AVCI, Portland, OR (US)

(21) Appl. No.: 17/485,302

(22) Filed: Sep. 24, 2021

(51) Int. Cl. H01L 29/76; H01L 29/24; H01L 29/06; H01L 29/423; H01L 29/45; H01L 29/786

(52) U.S. Cl. CPC H01L 29/7606; H01L 29/24; H01L 29/0665; H01L 29/42392; H01L 29/45; H01L 29/78696

(57) ABSTRACT

Embodiments of the disclosure are directed to advanced integrated circuit (IC) structure fabrication and, in particular, IC structures with an improved two-dimensional (2D) channel architecture. Other embodiments may be disclosed or claimed.

### TECHNICAL FIELD

Embodiments of the disclosure are in the field of advanced integrated circuit (IC) structure fabrication and, in particular, IC structures with an improved two-dimensional (2D) channel architecture.

### BACKGROUND

For the past several decades, the scaling of features in integrated circuits has been a driving force behind an ever-growing semiconductor industry. Scaling to smaller and smaller features enables increased densities of functional units on the limited real estate of semiconductor chips. For example, shrinking transistor size allows for the incorporation of an increased number of memory or logic devices on a chip, lending to the fabrication of products with increased capacity. The drive for ever-more capacity, however, is not without issue. The necessity to optimize the performance of each device becomes increasingly significant. Embodiments of the present disclosure address these and other issues.

### BRIEF DESCRIPTION OF THE DRAWINGS

FIGS. 1A, 1B, and 1C illustrate cross-sectional views of examples of IC structures in accordance with various embodiments of the present disclosure.

FIG. 2 illustrates an example of a computing device in accordance with various embodiments of the disclosure.

FIG. 3 illustrates an example of an interposer that includes one or more embodiments of the disclosure.

### DESCRIPTION OF THE EMBODIMENTS

In the following description, IC structures with an improved two-dimensional (2D) channel architecture are described. In the following description, numerous specific details are set forth, such as specific integration and material regimes, in order to provide a thorough understanding of embodiments of the present disclosure. It will be apparent to one skilled in the art that embodiments of the present disclosure may be practiced without these specific details. In other instances, well-known features, such as integrated circuit design layouts, are not described in detail in order to not unnecessarily obscure embodiments of the present disclosure. Furthermore, it is to be appreciated that the various embodiments shown in the Figures are illustrative representations and are not necessarily drawn to scale.

The following detailed description is merely illustrative in nature and is not intended to limit the embodiments of the subject matter or the application and uses of such embodiments. As used herein, the word “exemplary” means “serving as an example, instance, or illustration.” Any implementation described herein as exemplary is not necessarily to be construed as preferred or advantageous over other implementations. Furthermore, there is no intention to be bound by any expressed or implied theory presented in the preceding technical field, background, brief summary or the following detailed description.

This specification includes references to “one embodiment” or “an embodiment.” The appearances of the phrases “in one embodiment” or “in an embodiment” do not necessarily refer to the same embodiment. Particular features, structures, or characteristics may be combined in any suitable manner consistent with this disclosure.

Terminology. The following paragraphs provide definitions or context for terms found in this disclosure (including the appended claims):

“Comprising.” This term is open-ended. As used in the appended claims, this term does not foreclose additional structure or operations.

“Configured To.” Various units or components may be described or claimed as “configured to” perform a task or tasks. In such contexts, “configured to” is used to connote structure by indicating that the units or components include structure that performs those task or tasks during operation. As such, the unit or component can be said to be configured to perform the task even when the specified unit or component is not currently operational (e.g., is not on or active). Reciting that a unit or circuit or component is “configured to” perform one or more tasks is expressly intended not to invoke 35 U.S.C. § 112, sixth paragraph, for that unit or component.

“First,” “Second,” etc. As used herein, these terms are used as labels for nouns that they precede, and do not imply any type of ordering (e.g., spatial, temporal, logical, etc.).

“Coupled”—The following description refers to elements or nodes or features being “coupled” together. As used herein, unless expressly stated otherwise, “coupled” means that one element or node or feature is directly or indirectly joined to (or directly or indirectly communicates with) another element or node or feature, and not necessarily mechanically.

In addition, certain terminology may also be used in the following description for the purpose of reference only, and thus are not intended to be limiting. For example, terms such as “upper”, “lower”, “above”, and “below” refer to directions in the drawings to which reference is made. Terms such as “front”, “back”, “rear”, “side”, “outboard”, and “inboard” describe the orientation or location or both of portions of the component within a consistent but arbitrary frame of reference which is made clear by reference to the text and the associated drawings describing the component under discussion. Such terminology may include the words specifically mentioned above, derivatives thereof, and words of similar import.

“Inhibit”—As used herein, inhibit is used to describe a reducing or minimizing effect. When a component or feature is described as inhibiting an action, motion, or condition it may completely prevent the result or outcome or future state completely. Additionally, “inhibit” can also refer to a reduction or lessening of the outcome, performance, or effect which might otherwise occur. Accordingly, when a component, element, or feature is referred to as inhibiting a result or state, it need not completely prevent or eliminate the result or state.

Embodiments described herein may be directed to front-end-of-line (FEOL) semiconductor processing and structures. FEOL is the first portion of integrated circuit (IC) fabrication where the individual devices (e.g., transistors, capacitors, resistors, etc.) are patterned in the semiconductor substrate or layer. FEOL generally covers everything up to (but not including) the deposition of metal interconnect layers. Following the last FEOL operation, the result is typically a wafer with isolated transistors (e.g., without any wires).

Embodiments described herein may be directed to back-end-of-line (BEOL) semiconductor processing and structures. BEOL is the second portion of IC fabrication where the individual devices (e.g., transistors, capacitors, resistors, etc.) get interconnected with wiring on the wafer, e.g., the metallization layer or layers. BEOL includes contacts, insulating layers (dielectrics), metal levels, and bonding sites for chip-to-package connections. In the BEOL part of the fabrication stage contacts (pads), interconnect wires, vias and dielectric structures are formed. For modern IC processes, more than 10 metal layers may be added in the BEOL.

Embodiments described below may be applicable to FEOL processing and structures, BEOL processing and structures, or both FEOL and BEOL processing and structures. In particular, although an exemplary processing scheme may be illustrated using a FEOL processing scenario, such approaches may also be applicable to BEOL processing. Likewise, although an exemplary processing scheme may be illustrated using a BEOL processing scenario, such approaches may also be applicable to FEOL processing.

One or more embodiments may be implemented to realize a 3D ferroelectric RAM (FRAM, FeRAM, or F-RAM) to potentially increase monolithic integration of backend logic plus memory in SoCs of future technology nodes. To provide context, a FRAM is a random-access memory similar in construction to DRAM but uses a ferroelectric layer instead of a dielectric layer to achieve non-volatility. Conventionally, both FRAM and DRAM are one transistor (1T)/one capacitor (1C) cell arrays, where each cell comprises an access transistor in the front end coupled to a single capacitor. The capacitor may be coupled to a bitline (COB) higher in the stack in the semiconductor back end.

As introduced above, there are a number of challenges facing IC performance and fabrication. For example, issues arise with selective 2D material regrowth on a 2D crystal edge, which enables a 2D contact. For example, a 2D top contact may be required in some devices for low contact resistance (Rc). However, there is no proven 2D regrowth process. Among other things, embodiments of the present disclosure can provide a 2D top contact without the need for a 2D regrowth process.

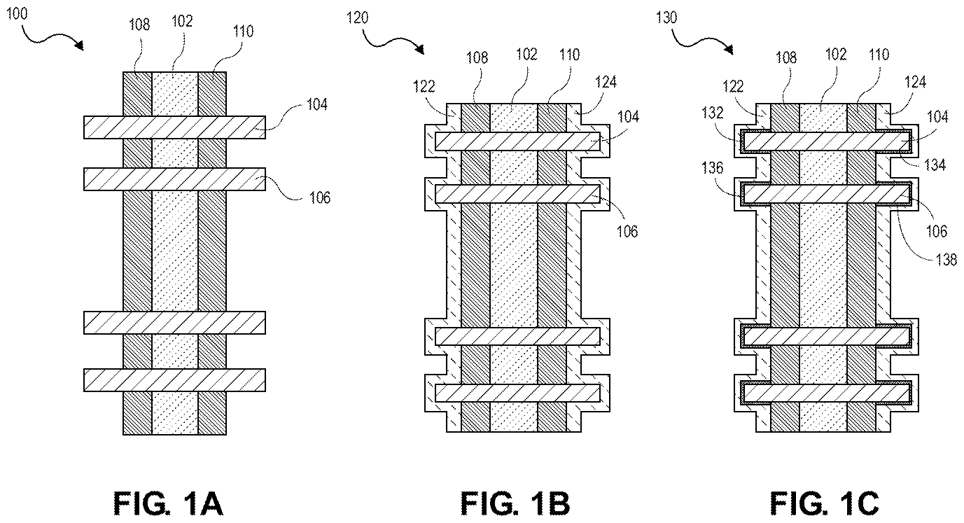

FIG. 1A illustrates a cross-section of an IC structure in accordance with various embodiments. In this example, IC structure 100 includes a sacrificial layer 102, and a first two-dimensional (2D) channel 104 and second 2D channel 106 coupled to the sacrificial layer 102, the 2D channels 104, 106 comprising a transition metal dichalcogenide (TMD) material. Spacer material layers 108, 110 are coupled to the sacrificial layer 102 and the 2D channels 104, 106.

As illustrated in FIGS. 1A-1C, the second 2D channel 106 is parallel to the first 2D channel 104 (and perpendicular to the spacer material layers 108, 110 and sacrificial layer 102), however other configurations may be possible in alternate embodiments. Additionally, the IC structure 100, 120, or 130 may include any suitable number of 2D channels. As used herein, the terms “parallel” and “perpendicular” are intended to mean “substantially parallel” and “substantially perpendicular.” For example, in some embodiments two structures may be substantially parallel or substantially perpendicular within +/−5 degrees.

The IC structure 100 shown in FIG. 1A may be achieved where the sacrificial material 102 between 2D nano-sheets is over-etched, and only partially refilled with the spacer material 108, 110. This method leaves some 2D crystal surface of channels 104, 106 exposed. This allows for a top contact directly on the 2D surface (as shown in FIG. 1B) or a deposition of doped 2D material on the surface (as shown in FIG. 1C). Among other things, embodiments of the present disclosure may be fabricated without the need for a complicated/unreliable regrowth process, as is the case for conventional devices. Additionally, embodiments of the present disclosure may be fabricated with a simplified integration flow and a grain-free high quality 2D crystal.

FIG. 1B illustrates an example of an IC structure where a metallic contact (e.g., top contact) is constructed directly on the surface of the 2D crystal surface. In this example, IC structure 120 includes the structure shown in FIG. 1A, with the addition of metallic contact layers 122, 124 coupled to the 2D channels 104, 106 and the spacer material layers 108, 110. In this example, the first spacer material layer 108 is between the first metallic contact layer 122 and the sacrificial layer 102, the second spacer material layer 110 is between the second metallic contact layer 124 and the sacrificial layer 102, and there is no grain boundary present in the 2D channels 104, 106 by the spacer material layer 108, 110.

The sacrificial layer 102 may include any suitable material or combination of materials. In some embodiments, for example, the sacrificial layer 102 comprises: Al2O3, AlN, GaN, Ge, Si, HZO, HfO2, ZrO2, SiO2, or SiN. Similarly, the TMD material of the 2D channels 104, 106 may include any suitable material or combination of materials, such as: WSe2, WS2, MoS2, MoSe2, or MoTe2.

The spacer material layers 108, 110 may include any suitable material or combination of materials. In some embodiments, for example, the spacer material layer comprises: Al2O3, AlN, GaN, SiO2, or SiN. The metallic contact layers 122, 124 may also include any suitable material or combination of materials. In some embodiments, for example, the metallic contact layer comprises: Au, Sb, Bi, Ru, Ag, Ni, Mg, Mn, Pd, or Pt.

In the example shown in FIG. 1B, the IC structure 120 may comprise a transistor. For example, the first metallic contact layer 122 may be a source of a transistor, and the second metallic contact layer 124 a drain of the transistor, or vice versa.

FIG. 1C illustrates a cross-sectional view of IC structure 100 with a doped 2D material on the surface of the 2D channels. In particular, IC structure 130 includes a similar structure and features to IC structure 120 in FIG. 1B, with the addition of doped 2D material layers 132, 134, 136, and 138 coupled to the 2D channels 104, 106.

For example, the first metallic contact layer 122 is coupled to the first 2D channel 104, the first spacer material layer 108, and the first doped 2D material layer 132. As also shown, the first spacer material layer 108 is between the first metallic contact layer 122 and the sacrificial layer 102. Additionally, the first doped 2D material layer 132 is between the first 2D channel 104 and the first metallic contact layer 122, and wherein there is no grain boundary in the first 2D channel 104 by the first spacer material layer 108.

Similarly, the second doped 2D material layer 134 is coupled to the first 2D channel 104, and the second metallic contact layer 124 is coupled to the second spacer material layer 110 and the second doped 2D material layer 134. The second spacer material layer 110 is between the second metallic contact layer 124 and the sacrificial layer 102, the second doped 2D material layer 134 is between the second metallic contact layer 124 and the first 2D channel 104, and there is no grain boundary in the first 2D channel 104 by the second spacer material layer 110.

Implementations of embodiments of the invention may be formed or carried out on a substrate, such as a semiconductor substrate. In one implementation, the semiconductor substrate may be a crystalline substrate formed using a bulk silicon or a silicon-on-insulator substructure. In other implementations, the semiconductor substrate may be formed using alternate materials, which may or may not be combined with silicon, that include but are not limited to germanium, indium antimonide, lead telluride, indium arsenide, indium phosphide, gallium arsenide, indium gallium arsenide, gallium antimonide, or other combinations of group III-V or group IV materials. Although a few examples of materials from which the substrate may be formed are described here, any material that may serve as a foundation upon which a semiconductor device may be built falls within the spirit and scope of the present invention.

A plurality of transistors, such as metal-oxide-semiconductor field-effect transistors (MOSFET or simply MOS transistors), may be fabricated on the substrate. In various implementations of the invention, the MOS transistors may be planar transistors, nonplanar transistors, or a combination of both. Nonplanar transistors include FinFET transistors such as double-gate transistors and tri-gate transistors, and wrap-around or all-around gate transistors such as nanoribbon and nanowire transistors. Although the implementations described herein may illustrate only planar transistors, it should be noted that the invention may also be carried out using nonplanar transistors.

Each MOS transistor includes a gate stack formed of at least two layers, a gate dielectric layer and a gate electrode layer. The gate dielectric layer may include one layer or a stack of layers. The one or more layers may include silicon oxide, silicon dioxide (SiO₂) and/or a high-k dielectric material. The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric layer include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric layer to improve its quality when a high-k material is used.

The gate electrode layer is formed on the gate dielectric layer and may consist of at least one P-type workfunction metal or N-type workfunction metal, depending on whether the transistor is to be a PMOS or an NMOS transistor. In some implementations, the gate electrode layer may consist of a stack of two or more metal layers, where one or more metal layers are workfunction metal layers and at least one metal layer is a fill metal layer.

For a PMOS transistor, metals that may be used for the gate electrode include, but are not limited to, ruthenium, palladium, platinum, cobalt, nickel, and conductive metal oxides, e.g., ruthenium oxide. A P-type metal layer will enable the formation of a PMOS gate electrode with a workfunction that is between about 4.9 eV and about 5.2 eV. For an NMOS transistor, metals that may be used for the gate electrode include, but are not limited to, hafnium, zirconium, titanium, tantalum, aluminum, alloys of these metals, and carbides of these metals such as hafnium carbide, zirconium carbide, titanium carbide, tantalum carbide, and aluminum carbide. An N-type metal layer will enable the formation of an NMOS gate electrode with a workfunction that is between about 3.9 eV and about 4.2 eV.

In some implementations, the gate electrode may consist of a “U”-shaped structure that includes a bottom portion substantially parallel to the surface of the substrate and two sidewall portions that are substantially perpendicular to the top surface of the substrate. In another implementation, at least one of the metal layers that form the gate electrode may simply be a planar layer that is substantially parallel to the top surface of the substrate and does not include sidewall portions substantially perpendicular to the top surface of the substrate. In further implementations of the invention, the gate electrode may consist of a combination of U-shaped structures and planar, non-U-shaped structures. For example, the gate electrode may consist of one or more U-shaped metal layers formed atop one or more planar, non-U-shaped layers.

In some implementations of the invention, a pair of sidewall spacers may be formed on opposing sides of the gate stack that bracket the gate stack. The sidewall spacers may be formed from a material such as silicon nitride, silicon oxide, silicon carbide, silicon nitride doped with carbon, and silicon oxynitride. Processes for forming sidewall spacers are well known in the art and generally include deposition and etching process steps. In an alternate implementation, a plurality of spacer pairs may be used, for instance, two pairs, three pairs, or four pairs of sidewall spacers may be formed on opposing sides of the gate stack.

As is well known in the art, source and drain regions are formed within the substrate adjacent to the gate stack of each MOS transistor. The source and drain regions are generally formed using either an implantation/diffusion process or an etching/deposition process. In the former process, dopants such as boron, aluminum, antimony, phosphorous, or arsenic may be ion-implanted into the substrate to form the source and drain regions. An annealing process that activates the dopants and causes them to diffuse further into the substrate typically follows the ion implantation process. In the latter process, the substrate may first be etched to form recesses at the locations of the source and drain regions. An epitaxial deposition process may then be carried out to fill the recesses with material that is used to fabricate the source and drain regions. In some implementations, the source and drain regions may be fabricated using a silicon alloy such as silicon germanium or silicon carbide. In some implementations the epitaxially deposited silicon alloy may be doped in situ with dopants such as boron, arsenic, or phosphorous. In further embodiments, the source and drain regions may be formed using one or more alternate semiconductor materials such as germanium or a group III-V material or alloy. And in further embodiments, one or more layers of metal and/or metal alloys may be used to form the source and drain regions.

One or more interlayer dielectrics (ILD) are deposited over the MOS transistors. The ILD layers may be formed using dielectric materials known for their applicability in integrated circuit structures, such as low-k dielectric materials. Examples of dielectric materials that may be used include, but are not limited to, silicon dioxide (SiO2), carbon doped oxide (CDO), silicon nitride, organic polymers such as perfluorocyclobutane or polytetrafluoroethylene, fluorosilicate glass (FSG), and organosilicates such as silsesquioxane, siloxane, or organosilicate glass. The ILD layers may include pores or air gaps to further reduce their dielectric constant.

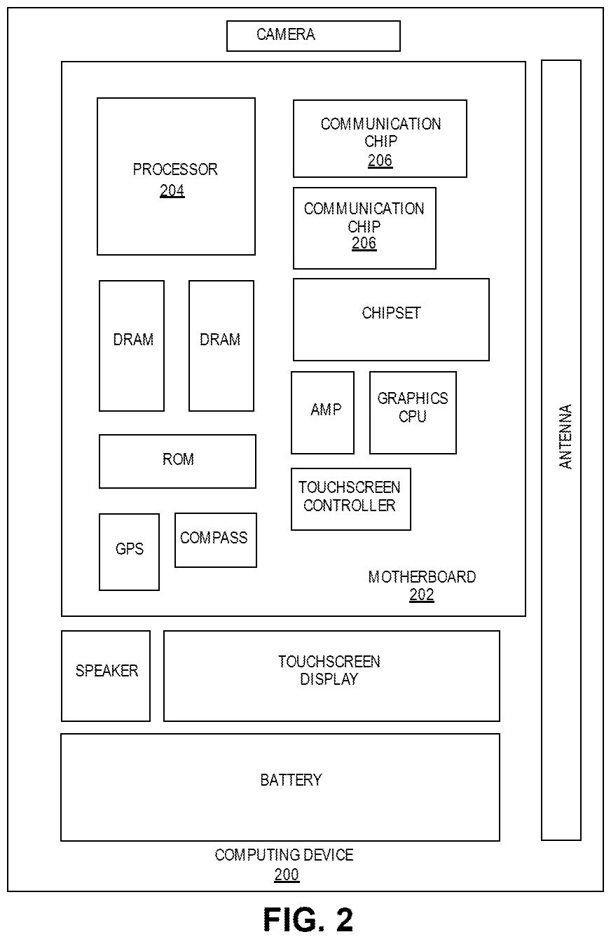

FIG. 2 illustrates a computing device 200 in accordance with one implementation of the invention. The computing device 200 houses a board 202. The board 202 may include a number of components, including but not limited to a processor 204 and at least one communication chip 206. The processor 204 is physically and electrically coupled to the board 202. In some implementations the at least one communication chip 206 is also physically and electrically coupled to the board 202. In further implementations, the communication chip 206 is part of the processor 204.

Depending on its applications, computing device 200 may include other components that may or may not be physically and electrically coupled to the board 202. These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 206 enables wireless communications for the transfer of data to and from the computing device 200. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 206 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 200 may include a plurality of communication chips 206. For instance, a first communication chip 206 may be dedicated to shorter range wireless communications such as Wi-Fi and Bluetooth and a second communication chip 206 may be dedicated to longer range wireless communications such as GPS, EDGE, GPRS, CDMA, WiMAX, LTE, Ev-DO, and others.

The processor 204 of the computing device 200 includes an integrated circuit die packaged within the processor 204. In some implementations of the invention, the integrated circuit die of the processor includes one or more devices, such as MOS-FET transistors built in accordance with implementations of the invention. The term “processor” may refer to any device or portion of a device that processes electronic data from registers and/or memory to transform that electronic data into other electronic data that may be stored in registers and/or memory.

The communication chip 206 also includes an integrated circuit die packaged within the communication chip 206. In accordance with another implementation of the invention, the integrated circuit die of the communication chip includes one or more devices, such as MOS-FET transistors built in accordance with implementations of the invention.

In further implementations, another component housed within the computing device 200 may contain an integrated circuit die that includes one or more devices, such as MOS-FET transistors built in accordance with implementations of the invention.

In various implementations, the computing device 200 may be a laptop, a netbook, a notebook, an ultrabook, a smartphone, a tablet, a personal digital assistant (PDA), an ultra-mobile PC, a mobile phone, a desktop computer, a server, a printer, a scanner, a monitor, a set-top box, an entertainment control unit, a digital camera, a portable music player, or a digital video recorder. In further implementations, the computing device 200 may be any other electronic device that processes data.

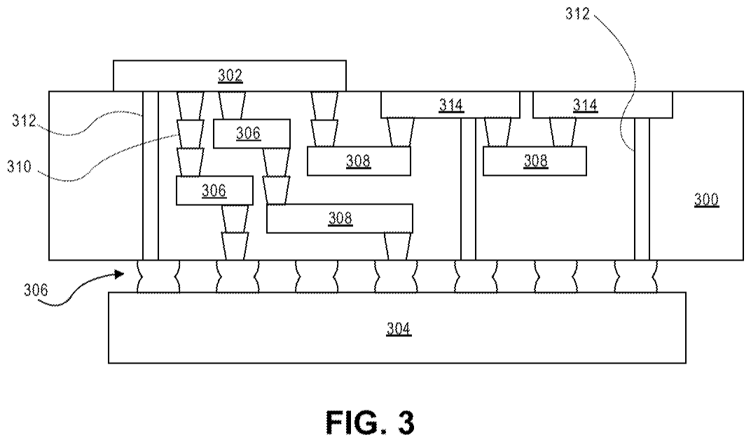

FIG. 3 illustrates an interposer 300 that includes one or more embodiments of the invention. The interposer 300 is an intervening substrate used to bridge a first substrate 302 to a second substrate 304. The first substrate 302 may be, for instance, an integrated circuit die. The second substrate 304 may be, for instance, a memory module, a computer motherboard, or another integrated circuit die. Generally, the purpose of an interposer 300 is to spread a connection to a wider pitch or to reroute a connection to a different connection. For example, an interposer 300 may couple an integrated circuit die to a ball grid array (BGA) 306 that can subsequently be coupled to the second substrate 304. In some embodiments, the first and second substrates 302/304 are attached to opposing sides of the interposer 300. In other embodiments, the first and second substrates 302/304 are attached to the same side of the interposer 300. And in further embodiments, three or more substrates are interconnected by way of the interposer 300.

The interposer 300 may be formed of an epoxy resin, a fiberglass-reinforced epoxy resin, a ceramic material, or a polymer material such as polyimide. In further implementations, the interposer 300 may be formed of alternate rigid or flexible materials that may include the same materials described above for use in a semiconductor substrate, such as silicon, germanium, and other group III-V and group IV materials.

The interposer 300 may include metal interconnects 308 and vias 310, including but not limited to through-silicon vias (TSVs) 312. The interposer 300 may further include embedded devices 314, including both passive and active devices. Such devices include, but are not limited to, capacitors, decoupling capacitors, resistors, inductors, fuses, diodes, transformers, sensors, and electrostatic discharge (ESD) devices. More complex devices such as radio-frequency (RF) devices, power amplifiers, power management devices, antennas, arrays, sensors, and MEMS devices may also be formed on the interposer 300. In accordance with embodiments of the invention, apparatuses or processes disclosed herein may be used in the fabrication of interposer 300.

Although specific embodiments have been described above, these embodiments are not intended to limit the scope of the present disclosure, even where only a single embodiment is described with respect to a particular feature. Examples of features provided in the disclosure are intended to be illustrative rather than restrictive unless stated otherwise. The above description is intended to cover such alternatives, modifications, and equivalents as would be apparent to a person skilled in the art having the benefit of the present disclosure.

The scope of the present disclosure includes any feature or combination of features disclosed herein (either explicitly or implicitly), or any generalization thereof, whether or not it mitigates any or all of the problems addressed herein. Accordingly, new claims may be formulated during prosecution of the present application (or an application claiming priority thereto) to any such combination of features. In particular, with reference to the appended claims, features from dependent claims may be combined with those of the independent claims and features from respective independent claims may be combined in any appropriate manner and not merely in the specific combinations enumerated in the appended claims.

The following examples pertain to further embodiments. The various features of the different embodiments may be variously combined with some features included and others excluded to suit a variety of different applications.

Example embodiment 1 includes an integrated circuit structure, comprising: a sacrificial layer; a two-dimensional (2D) channel coupled to the sacrificial layer, the 2D channel comprising a transition metal dichalcogenide (TMD) material; a spacer material layer coupled to the sacrificial layer and the 2D channel; and a metallic contact layer coupled to the 2D channel and the spacer material layer, wherein the spacer material layer is between the metallic contact layer and the sacrificial layer, and wherein there is no grain boundary in the 2D channel by the spacer material layer.

Example embodiment 2 includes the integrated circuit structure of Example embodiment 1 or some other example herein, wherein the sacrificial layer comprises: Al2O3, AlN, GaN, Ge, Si, HZO, HfO2, ZrO2, SiO2, or SiN.

Example embodiment 3 includes the integrated circuit structure of Example embodiments 1 or 2 or some other example herein, wherein the TMD material of the 2D channel comprises: WSe2, WS2, MoS2, MoSe2, or MoTe2.

Example embodiment 4 includes the integrated circuit structure of any of Example embodiments 1-3 or some other example herein, wherein the spacer material layer comprises: Al2O3, AlN, GaN, SiO2, or SiN.

Example embodiment 5 includes the integrated circuit structure of any of Example embodiments 1-4 or some other example herein, wherein the metallic contact layer comprises: Au, Sb, Bi, Ru, Ag, Ni, Mg, Mn, Pd, or Pt.

Example embodiment 6 includes the integrated circuit structure of Example embodiment 1 or some other example herein, wherein the spacer material layer is a first spacer material layer, and the metallic contact layer is a first metallic contact layer, the integrated circuit structure further comprising: a second spacer material layer coupled to the sacrificial layer; and a second metallic contact layer coupled to the 2D channel and the second spacer material layer, wherein the second spacer material layer is between the second metallic contact layer and the sacrificial layer, and wherein there is no grain boundary in the 2D channel by the second spacer material layer.

Example embodiment 7 includes the integrated circuit structure of Example embodiment 6 or some other example herein, wherein the first metallic contact layer is a source of a transistor, and the second metallic contact layer is a drain of the transistor.

Example embodiment 8 includes the integrated circuit structure of Example embodiment 6 or some other example herein, wherein the 2D channel is a first 2D channel, the integrated circuit structure further comprising: a second 2D channel coupled to the sacrificial layer, the first spacer material layer, the second spacer material layer, the first metallic contact layer, and the second metallic contact layer, wherein the second 2D channel comprises the TMD material.

Example embodiment 9 includes the integrated circuit structure of Example embodiment 8 or some other example herein, wherein the second 2D channel is parallel to the first 2D channel.

Example embodiment 10 includes an integrated circuit structure, comprising: a sacrificial layer; a two-dimensional (2D) channel coupled to the sacrificial layer, the 2D channel comprising a transition metal dichalcogenide (TMD) material; a spacer material layer coupled to the sacrificial layer and the 2D channel; a doped 2D material layer coupled to the 2D channel; and a metallic contact layer coupled to the 2D channel, the spacer material layer, and the doped 2D material layer, wherein the spacer material layer is between the metallic contact layer and the sacrificial layer, wherein the doped 2D material layer is between the 2D channel and the metallic contact layer, and wherein there is no grain boundary in the 2D channel by the spacer material layer.

Example embodiment 11 includes the integrated circuit structure of Example embodiment 10 or some other example herein, wherein the doped 2D material layer includes a TMD material doped with: V, Nb, Ta, Mn, Re, P, As, Sb, or Br.

Example embodiment 12 includes the integrated circuit structure of Example embodiments 10 or 11 or some other example herein, wherein the sacrificial layer comprises: Al2O3, AlN, GaN, Ge, Si, HZO, HfO2, ZrO2, SiO2, or SiN.

Example embodiment 13 includes the integrated circuit structure of any of Example embodiments 10-12 or some other example herein, wherein the TMD material of the 2D channel comprises: WSe2, WS2, MoS2, MoSe2, or MoTe2.

Example embodiment 14 includes the integrated circuit structure of any of Example embodiments 10-13 or some other example herein, wherein the spacer material layer comprises: Al2O3, AlN, GaN, SiO2, or SiN.

Example embodiment 15 includes the integrated circuit structure of Example embodiment 10 or some other example herein, wherein the metallic contact layer comprises: Au, Sb, Bi, Ru, Ag, Ni, Mg, Mn, Pd, or Pt.

Example embodiment 16 includes the integrated circuit structure of Example embodiment 10 or some other example herein, wherein the spacer material layer is a first spacer material layer, the metallic contact layer is a first metallic contact layer, and the doped 2D material layer is a first doped 2D material layer, the integrated circuit structure further comprising: a second spacer material layer coupled to the sacrificial layer; a second doped 2D material layer coupled to the 2D channel; and a second metallic contact layer coupled to the second spacer material layer and the second doped 2D material layer, wherein the second spacer material layer is between the second metallic contact layer and the sacrificial layer, wherein the second doped 2D material layer is between the second metallic contact layer and the 2D channel, and wherein there is no grain boundary in the 2D channel by the second spacer material layer.

Example embodiment 17 includes the integrated circuit structure of Example embodiment 16 or some other example herein, wherein the first metallic contact layer is a source of a transistor, and the second metallic contact layer is a drain of the transistor.

Example embodiment 18 includes the integrated circuit structure of Example embodiment 16 or some other example herein, wherein the 2D channel is a first 2D channel, the integrated circuit structure further comprising: a second 2D channel coupled to the sacrificial layer, the first spacer material layer, the second spacer material layer, a third doped 2D material layer, and a fourth doped 2D material layer, wherein the second 2D channel comprises the transition metal dichalcogenide (TMD) material, wherein the third doped 2D material layer is between the first metallic contact layer and the second 2D channel, and wherein the fourth doped 2D material layer is between the second metallic contact layer and the second 2D channel.

Example embodiment 19 includes the integrated circuit structure of Example embodiment 18 or some other example herein, wherein the second 2D channel is parallel to the first 2D channel.

Example embodiment 20 includes a computing device, comprising: a board; and a component coupled to the board, the component including an integrated circuit structure, comprising: a sacrificial layer; a two-dimensional (2D) channel coupled to the sacrificial layer, the 2D channel comprising a transition metal dichalcogenide (TMD) material; a spacer material layer coupled to the sacrificial layer and the 2D channel; and a metallic contact layer coupled to the 2D channel and the spacer material layer, wherein the spacer material layer is between the metallic contact layer and the sacrificial layer, and wherein there is no grain boundary in the 2D channel by the spacer material layer.

Example 21 includes the computing device of Example embodiment 20 or some other example herein, further comprising a processor coupled to the board, a communication chip coupled to the board, or a camera coupled to the board.

Example 22 includes the computing device of Example embodiment 20 or some other example herein, wherein the component is a packaged integrated circuit die.

Example embodiment 23 includes a computing device, comprising: a board; and a component coupled to the board, the component including an integrated circuit structure, comprising: a sacrificial layer; a two-dimensional (2D) channel coupled to the sacrificial layer, the 2D channel comprising a transition metal dichalcogenide (TMD) material; a spacer material layer coupled to the sacrificial layer and the 2D channel; a doped 2D material layer coupled to the 2D channel; and a metallic contact layer coupled to the 2D channel, the spacer material layer, and the doped 2D material layer, wherein the spacer material layer is between the metallic contact layer and the sacrificial layer, wherein the doped 2D material layer is between the 2D channel and the metallic contact layer, and wherein there is no grain boundary in the 2D channel by the spacer material layer.

Example 24 includes the computing device of Example embodiment 23 or some other example herein, further comprising a processor coupled to the board, a communication chip coupled to the board, or a camera coupled to the board.

What is claimed is:

1. An integrated circuit structure, comprising:
a sacrificial layer;
a two-dimensional (2D) channel coupled to the sacrificial layer, the 2D channel comprising a transition metal dichalcogenide (TMD) material;
a spacer material layer coupled to the sacrificial layer and the 2D channel; and
a metallic contact layer coupled to the 2D channel and the spacer material layer, wherein the spacer material layer is between the metallic contact layer and the sacrificial layer, and wherein there is no grain boundary in the 2D channel by the spacer material layer.

2. The integrated circuit structure of claim 1, wherein the sacrificial layer comprises: Al2O3, AlN, GaN, Ge, Si, HZO, HfO2, ZrO2, SiO₂, or SiN.

3. The integrated circuit structure of claim 1, wherein the TMD material of the 2D channel comprises: WSe2, WS2, MoS2, MoSe2, or MoTe2.

4. The integrated circuit structure of claim 1, wherein the spacer material layer comprises: Al2O3, AlN, GaN, SiO₂, or SiN.

5. The integrated circuit structure of claim 1, wherein the metallic contact layer comprises: Au, Sb, Bi, Ru, Ag, Ni, Mg, Mn, Pd, or Pt.

6. The integrated circuit structure of claim 1, wherein the spacer material layer is a first spacer material layer, and the metallic contact layer is a first metallic contact layer, the integrated circuit structure further comprising:
a second spacer material layer coupled to the sacrificial layer; and
a second metallic contact layer coupled to the 2D channel and the second spacer material layer, wherein the second spacer material layer is between the second metallic contact layer and the sacrificial layer, and wherein there is no grain boundary in the 2D channel by the second spacer material layer.

7. The integrated circuit structure of claim 6, wherein the first metallic contact layer is a source of a transistor, and the second metallic contact layer is a drain of the transistor.

8. The integrated circuit structure of claim 6, wherein the 2D channel is a first 2D channel, the integrated circuit structure further comprising:
a second 2D channel coupled to the sacrificial layer, the first spacer material layer, the second spacer material layer, the first metallic contact layer, and the second metallic contact layer, wherein the second 2D channel comprises the TMD material.

9. The integrated circuit structure of claim 8, wherein the second 2D channel is parallel to the first 2D channel.

10. An integrated circuit structure, comprising:
a sacrificial layer;
a two-dimensional (2D) channel coupled to the sacrificial layer, the 2D channel comprising a transition metal dichalcogenide (TMD) material;
a spacer material layer coupled to the sacrificial layer and the 2D channel;
a doped 2D material layer coupled to the 2D channel; and
a metallic contact layer coupled to the 2D channel, the spacer material layer, and the doped 2D material layer, wherein the spacer material layer is between the metallic contact layer and the sacrificial layer, wherein the doped 2D material layer is between the 2D channel and the metallic contact layer, and wherein there is no grain boundary in the 2D channel by the spacer material layer.

11. The integrated circuit structure of claim 10, wherein the doped 2D material layer includes a TMD material doped with: V, Nb, Ta, Mn, Re, P, As, Sb, or Br.

12. The integrated circuit structure of claim 10, wherein the sacrificial layer comprises: Al2O3, AlN, GaN, Ge, Si, HZO, HfO2, ZrO2, SiO2, or SiN.

13. The integrated circuit structure of claim 10, wherein the TMD material of the 2D channel comprises: WSe2, WS2, MoS2, MoSe2, or MoTe2.

14. The integrated circuit structure of claim 10, wherein the spacer material layer comprises: Al2O3, AlN, GaN, SiO2, or SiN.

15. The integrated circuit structure of claim 10, wherein the metallic contact layer comprises: Au, Sb, Bi, Ru, Ag, Ni, Mg, Mn, Pd, or Pt.

16. The integrated circuit structure of claim 10, wherein the spacer material layer is a first spacer material layer, the metallic contact layer is a first metallic contact layer, and the doped 2D material layer is a first doped 2D material layer, the integrated circuit structure further comprising:
a second spacer material layer coupled to the sacrificial layer;
a second doped 2D material layer coupled to the 2D channel; and
a second metallic contact layer coupled to the second spacer material layer and the second doped 2D material layer, wherein the second spacer material layer is between the second metallic contact layer and the sacrificial layer, wherein the second doped 2D material layer is between the second metallic contact layer and the 2D channel, and wherein there is no grain boundary in the 2D channel by the second spacer material layer.

17. The integrated circuit structure of claim 16, wherein the first metallic contact layer is a source of a transistor, and the second metallic contact layer is a drain of the transistor.

18. The integrated circuit structure of claim 16, wherein the 2D channel is a first 2D channel, the integrated circuit structure further comprising:
a second 2D channel coupled to the sacrificial layer, the first spacer material layer, the second spacer material layer, a third doped 2D material layer, and a fourth doped 2D material layer, wherein the second 2D channel comprises the transition metal dichalcogenide (TMD) material, wherein the third doped 2D material layer is between the first metallic contact layer and the second 2D channel, and wherein the fourth doped 2D material layer is between the second metallic contact layer and the second 2D channel.

19. The integrated circuit structure of claim 18, wherein the second 2D channel is parallel to the first 2D channel.

20. A computing device, comprising:
a board; and
a component coupled to the board, the component including an integrated circuit structure, comprising:
a sacrificial layer;
a two-dimensional (2D) channel coupled to the sacrificial layer, the 2D channel comprising a transition metal dichalcogenide (TMD) material;
a spacer material layer coupled to the sacrificial layer and the 2D channel; and
a metallic contact layer coupled to the 2D channel and the spacer material layer, wherein the spacer material layer is between the metallic contact layer and the sacrificial layer, and wherein there is no grain boundary in the 2D channel by the spacer material layer.

21. The computing device of claim 20, further comprising a processor coupled to the board, a communication chip coupled to the board, or a camera coupled to the board.

22. The computing device of claim 20, wherein the component is a packaged integrated circuit die.

23. A computing device, comprising:
a board; and
a component coupled to the board, the component including an integrated circuit structure, comprising:
a sacrificial layer;
a two-dimensional (2D) channel coupled to the sacrificial layer, the 2D channel comprising a transition metal dichalcogenide (TMD) material;
a spacer material layer coupled to the sacrificial layer and the 2D channel;
a doped 2D material layer coupled to the 2D channel; and
a metallic contact layer coupled to the 2D channel, the spacer material layer, and the doped 2D material layer, wherein the spacer material layer is between the metallic contact layer and the sacrificial layer, wherein the doped 2D material layer is between the 2D channel and the metallic contact layer, and wherein there is no grain boundary in the 2D channel by the spacer material layer.

24. The computing device of claim 23, further comprising a processor coupled to the board, a communication chip coupled to the board, or a camera coupled to the board.
